(19) United States
(12) Patent Application Publication
(10) Pub. No.: US 2025/0201302 A1
(43) Pub. Date: Jun. 19, 2025

(54) FAST, ENERGY EFFICIENT CMOS 2P1R1W REGISTER FILE ARRAY USING HARVESTED DATA

(71) Applicant: Metis Microsystems, LLC, Newtown, CT (US)

(72) Inventor: Azeez BHAVNAGARWALA, Newtown, CT (US)

(73) Assignee: Metis Microsystems, LLC, Newtown, CT (US)

(21) Appl. No.: 18/784,279

(22) Filed: Jul. 25, 2024

Related U.S. Application Data
(63) Continuation of application No. 18/748,891, filed on Jun. 20, 2024, now abandoned.
Application No. 18/748,891 is a continuation of application No. 17/951,049, filed on Sep. 22, 2022, now abandoned.
Application No. 17/951,049 is a continuation of application No. 17/578,482, filed on Jan. 19, 2022, now Pat. No. 12,046,278.
(60) Provisional application No. 63/247,136, filed on Sep. 22, 2021.
(60) Provisional application No. 63/138,456, filed on Jan. 17, 2021.

(51) Int. Cl. G11C 11/419

(52) U.S. Cl. CPC G11C 11/419

(57) ABSTRACT

A transistor memory device includes storage elements storing a capacitance including (1) a capacitance at a source of PFETs, (2) a capacitance at each storage element connected to a storage node and (3) a capacitance at a gate input of inverter transistors from the plurality of transistor storage elements. Each storage element configured to perform (i) a read data access (ii) a write data access, to increase static noise margin. The transistor memory device further includes a harvest node coupled to a ground and that is configured to store a harvested charge transferred from a selected bitline to increase an output voltage at the harvest node. The transistor memory device further includes a capacitor divider configured to maintain a voltage swing on a bitline. The transistor memory device further includes a harvest circuit configured to, in response to the read data access, decouple the harvest node and invert a voltage.

### CROSS-REFERENCE TO RELATED APPLICATIONS

This application claims priority to and is a continuation of U.S. patent application Ser. No. 18/748,891 filed Jun. 20, 2024, entitled “Fast, Energy Efficient CMOS 2P1R1 W Register File Array Using Harvested Data,” which is a continuation of U.S. patent application Ser. No. 17/951,049, filed Sep. 22, 2022, entitled “Fast, Energy Efficient CMOS 2P1R1 W Register File Array using Harvested Data,” which is a continuation of U.S. patent application Ser. No. 17/578,482, filed Jan. 19, 2022 entitled “Fast, Energy Efficient Cmos 2p1r1w Register File Array Using Harvested Data”, which claims priority to U.S. Provisional Application No. 63/247,136, filed Sep. 22, 2021, entitled “Fast, Energy Efficient Cmos 2p1r1w Register File Array Using Harvested Data”, and U.S. Provisional Application No. 63/138,456, filed Jan. 17, 2021, entitled “Fast, Energy Efficient Cmos 2p1r1w Register File Array Using Harvested Data”, each of which is hereby incorporated by reference in its entirety. The application claims priority to U.S. Provisional Application No. 63/115,591, filed Nov. 18, 2020, entitled “Energy Efficient CMOS 2P1R1 W Register File Array using Harvested Data,” the contents of which are hereby incorporated by reference in its entirety.

### FIELD

The present disclosure generally relates to digital integrated circuits. In particular, the present disclosure is related to fast, energy efficient CMOS 2P1R1 W Register File Array using Harvested Data.

### BACKGROUND

While power density of CMOS chips was held constant with constant electric field (Dennard) scaling for over 30 years, increases in CMOS device variability at lower operating voltages and scaled geometries in tandem with reductions in circuit speed from non-scaling of gate overdrive due to exponential increases in leakage from scaling MOSFET threshold voltages limited CMOS voltages from scaling to much below 1 V. These trends brought an end to Dennard scaling in (FIG. 1a) in 2004. At constant voltage scaling, power density increases as the cube of scaling factor limiting processor clock frequencies to below 5 GHz during the last 15 years.

### SUMMARY

In some embodiments, a transistor memory device includes a plurality of transistor storage elements storing a collective capacitance including (1) a capacitance at a source terminal of each p-channel field-effect transistors (PFETs) from a plurality of PFETs, (2) a capacitance at each transistor storage element from the plurality of transistor storage elements electrically connected to a storage node and (3) a capacitance at a gate input of a plurality of inverter transistors from the plurality of transistor storage elements. Each transistor storage element from the plurality of transistor storage elements includes a word line port configured to select (a) a bitcell and (b) a first bitline or a second bitline. Each transistor storage element from the plurality of transistor storage elements is configured to perform (i) a read data access from or (ii) a write data access to each remaining transistor storage element from the plurality of transistor storage elements, to increase a static noise margin in response to a decrease of a read current and a voltage on the storage node. The collective capacitance of the plurality of transistor storage elements is greater than a terminal capacitance of the selected bitline. The transistor memory device further includes a harvest node electrically coupled to a ground and that is configured to store a harvested charge transferred from the selected bitline to increase an output voltage at the harvest node. The transistor memory device further includes a capacitor divider electrically connected between the selected bitline and the harvest node of a first transistor storage element from the plurality of transistor storage elements that shares the selected bitline and the harvest node. The capacitor divider is configured to maintain a voltage swing on the selected bitline. The transistor memory device further includes a harvest circuit electrically coupled to the harvest node and configured to, in response to the read data access performed by the first transistor storage element, decouple the harvest node from the ground and invert a voltage equal to a potential difference between the selected bitline and the harvest node.

### BRIEF DESCRIPTION OF DRAWINGS

FIG. 1A-1B is an illustration of a graphs depicting an end of Dennard Scaling, where CMOS performance is limited by cubic increase in power density with non-scaling of operating voltage and heat removal with more sophisticated and expensive packaging possible, but not for much longer, as red diamonds, according to some embodiment.

FIG. 2 is an illustrative representation of energy consumption limited by energy cost of moving data, according to some embodiment.

FIG. 3 is an illustrative representation of dataflows depicting improving energy efficiency with maximum data reuse and local RF access, according to some embodiment.

FIG. 4A-4B is a schematic illustration of a conventional 2P 1R1 W Register File bit path and an illustrative representation of a graph depicting waveforms during Read Access in a conventional 2P 1R1 W Register File bit path, according to some embodiment.

FIG. 5 is a schematic illustration of a layout of a conventional 2P RF bitcell, according to some embodiment.

FIG. 6A-6B is an illustrative representation of a PBTI stress condition on N2 equivalent to seen in transistor NR1 of RF bitcell and VT shift due to PBT1 in SRAM bitcells over a period of 100M secs (3 years) (worse for wider devices): 10 mV-15 mV with sigma VT adder: 2 mV-4 mV, according to some embodiment.

FIG. 7A-7B is a schematic illustration of an array architecture and Assist circuits of an 8 KB RF Array in 16FF CMOS using a non-hierarchical 8:1 column multiplexing for writes and an illustrative representation of a graph depicting Wiring parasitic parameters of 185 fF/um and 0.95 ohms/sq for Mx lines, according to some embodiment.

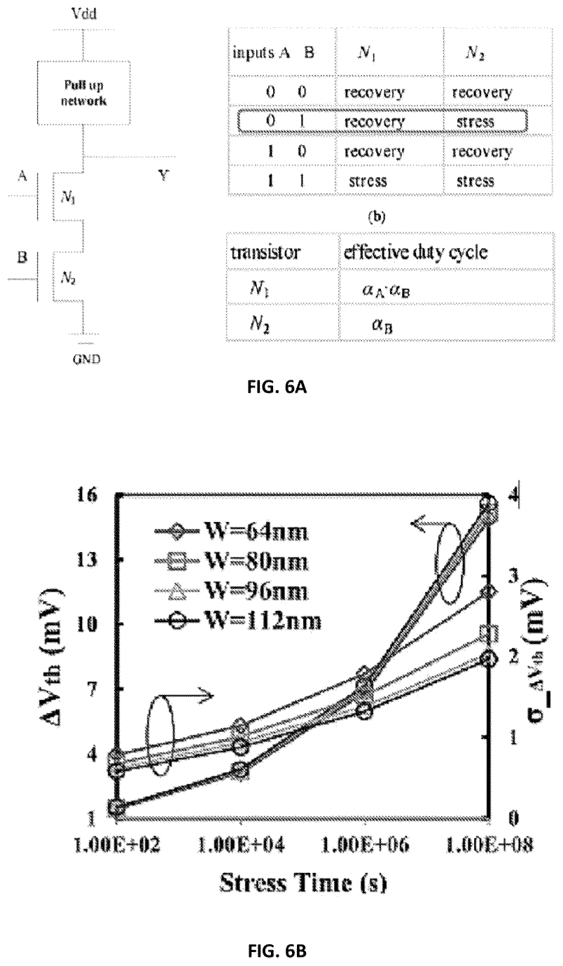

FIG. 8 is an illustrative representation of dimensions and wiring parasitics of RF array are used in the design of peripheral circuits to compare metrics of performance and energy efficiency of component using either proposed or conventional circuits. The array shown below assumes Global I/O and Control in the middle and not at the bottom as seen in FIG. 6. This because the bit path wire resistance could be less limiting in response time, according to some embodiment.
Local Decode, Datapath Control Logic-includes Local WL decode logic, Reset, LBL pre-charge, data path harvest control.
Global I/O, Control-Address<0:10>, Data in, out<0:31>, CLK, R/W.
8:1 Column mux for Write assumed. Global I/O & Control placed in middle of instance to limit R of pitch constrained Global BLs.
RWL, WWL: 128b (100 um): Cw=128×0.767 um×1.02×0.185fF/um=18.52fF. (R=0.95 ohms/sq with double metal lines RRWL=475 ohms)
LBL: 16b (3.45 um): Cw=16×0.18 um×1.2×0.185fF/um=0.64fF. RLBL=33 ohms
GRBL, GWBL: 224b (50.4 um): Cw=224×0.18 um×1.25×0.185fF/um=9.324fF RGRBL=475 ohms.

FIG. 9A-9B is a schematic illustration of a circuit schematic of a proposed 2P 1R1 W Register File bit path. LBL response to a WL select edge and the accompanying harvest of signal charge from LBL to V2L, according to some embodiment. This sensing scheme eliminates the need for a Sense Amp Enable signal (when differential sensing is used) and its accompanying overheads in performance, power and area, emulates a bitcell with twice the read current and consumes much less power with self-disabling action when sensed data is captured. The proposed scheme is energy efficient relative to large signal sensing as well since these dissipate all of the charge on the LBL. Conv circuits continue discharging the LBL even after sensed data has been latched. Moreover, harvested charge from the GRBL can lower Write energy by over 30% using harvested charge on V2 and have more available to further reduce energy consumed by WL drivers, decoders and control ckts.

FIG. 10 is a schematic illustration of a RF bitcell with GND contact of Read Stack replaced with V2L in proposed scheme—wire that runs parallel to and is similar t the LBL in length & capacitance, according to some embodiment.

FIG. 11 is an illustrative representation of a higher harvest voltage on global harvesting node in each column, V2G self-limits signal development on GRBL with substantial reduction in Global bitline energy consumption, according to some embodiment. V2G: ˜ 20.2 mm so that CV2G/CGRBL ˜0.4. This capacitance divider ratio drives limited charge from Read signal developed on the GRBL to be driven to a higher voltage enabling faster sensing action: V_{V2G}=ΔQ/C_{V2G}=ΔV_{GRBL}·(C_{GRBL}/C_{V2G}).

FIG. 12A-12B is an illustrative representation of a generation and synchronization of bitpath control signals and a graph depicting waveforms from circuit simulations, according to some embodiment.

FIG. 13 is an illustrative representation of a graph depicting with noise of 0.3V applied to Gate input of NR1 in the read stack, for longer WL pulse widths, the LBL is discharged through the read stack, flipping the output of the Global Read BL incorrectly due to the disturb noise in the half-selected RF cell in conventional bitpaths without the keeper circuits, according to some embodiment.

FIG. 14 is an illustrative representation of a graph noise of 0.3V applied to Gate input of NR1 in the read stack of the RF bitcell, V2L asymptotically increases to equalize the noise voltage while disabling the read stack by lowering Gate overdrive of NR1 to below VT into the subthreshold region. The read stack in the bitcell thus cannot evaluate the LBL to an incorrect value—as it would when conventional RF array peripheral circuits are used (FIG. 12A or FIG. 12B), according to some embodiment.

FIG. 15A is a schematic illustration of a decode path of Block Select and RWL. Not shown (for simplicity) is RE·CLK′ that gates pre-decider outputs to each Block.

FIG. 15B is an illustrative representation of a a decode path for WWL, and a decode stage used instead of a conv static CMOS NAND2 corresponding to gates highlighted in blue in FIG. 15a, according to some embodiment.

FIG. 16A is a schematic illustration of GWBL (D_in) drivers using charge harvested on the V2 grid to lower their energy consumption by over 30%, according to some embodiment.

FIG. 16B is an illustrative representation of a chematic of GWBL (D_in) driver that uses charge harvested on V2G (in FIGS. 9, 11) to lower its energy consumption by over 30%, according to some embodiment. Current drawn from VDD by this harvest charge using driver is shown by the red waveform above and compared to the current drawn from VDD by a conventional driver (shown by the blue waveform).

FIG. 17 is an illustrative representation of charge harvested from GRBL on to V2G in each bit column during a Read access is moved to a V2 grid as shown in FIG. 11 before the next Read access, according to some embodiment. V2 lines are connected enabling local decode, control, global I/O and control circuits to use this aggregate of harvested charge as well. Harvested charge on the V2 grid is immediately available for GWBL line drivers to use during a Write access. For a typical MAC operation, a Write access for every 3 Read accesses leave substantial charge on the V2 grid reservoir for Decode, control, I/O circuits and for components external to the array to use.

FIG. 18A-18B is an illustrative representation of a graph depicting voltage of charge on harvest grid V2 asymptotically approaches (with only Read operations) the voltage of node V2G schematic shown in FIG. 9 and a graph depicting the relative activity of a Write column, the V2 grid approaches 0.5 V, that enables harvester in FIG. 15 to lower GWBL driver energy by over 30%, according to some embodiment.

FIG. 19A-19B is an illustrative representation of a graph depicting voltage waveform and WL->G_out delay components along a Read Bitpath in a conventional RF Array and a graph depicting volt age and current waveform of ta Bitpath in a conventional RF array, according to some embodiment.

FIG. 20A is an illustrative representation of a graph depicting voltage waveform and WL->G_out delay components along a Read Bitpath in an RF Array with proposed circuits, according to some embodiment.

FIG. 20B is an illustrative representation of a graph depicting a voltage waveform WL->G_out delay components along a Read Bitpath in an RF Array with proposed circuits and with LVT devices NR1 and NR2 in the bit cell. Leakage from the array is unchanged, but WL Select->Global Data_out improves the equivalent delay in a conventional RF Array by over 50% (P1 see. FIG. 19a and Table I for more comparisons), according to some embodiment.

FIG. 20C is an illustrative representation of a graph depicting a 2×2 layout of the 16FF Foundry 1R1 W bitcell showing opportunity to lower the VT of the decoupled Read stack using an LVT mask (region highlighted in dashed box) for even higher performance without being constrained by leakage of the Read stack when using proposed harvesting schemes, according to some embodiment.

FIG. 20D is an illustrative representation of a graph depicting a Read and Write Bitpath response in Proposed Harvesting scheme, according to some embodiment. Quantitative comparison of WL->Data_out delay and bitpath energy consumption.

FIG. 21 is an illustrative representation of a comparison of Read and Write Energy Consumption of Proposed charge harvesting scheme with conventional RF array designs, according to some embodiment.

FIG. 22 is a schematic illustration of leakage paths along decoupled Read stack in conventional arrays (top) and in the arrays with proposed circuits (bottom), according to some embodiment. In proposed scheme, unlike conventional arrays, leakage is independent of the number of bitcells per LBL, of NFET Read Stack device VT and of data stored in bitcell,

FIG. 23 is an illustrative representation of a graph depicting leakage along the Read path in propped RF arrays can be orders of magnitude lower for array designs with 16 or more bitcells per LBL, according to some embodiment. Leakage along Read path of proposed RF arrays independent of number of Bit cells per LBL, independent of device VT of read stack NFETs in bit cell and also independent of data stored in bitcell.

### DETAILED DESCRIPTION

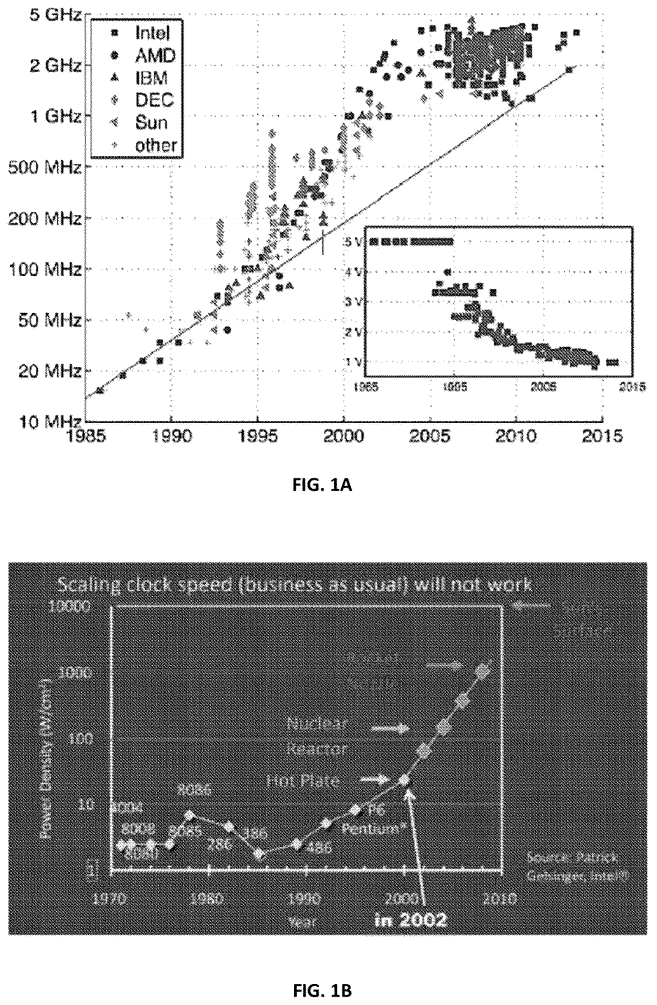

The end of Dennard scaling end the lack of greater instruction-level parallelism forced the industry to switch from a single-energy-intensive core per microprocessor to multiple efficient cores per chip with roll-outs of the industry's first dual. The move to parallel processing allowed each core to be more energy efficient by having a lower peak performance (at reduced supply voltage), with multiple cores on the die to increase the overall throughput performance. With Dennard scaling dead since 2004 and Moore's Law slowing to a doubling of transistor count every 20 years, transistors are not getting much faster while the peak power per mm² increases because voltages cannot scale anymore. Power budgets cannot increase either due to heat removal limits (FIG. 1b). Thus, performance limits on CMOS processors have been increasingly imposed by their energy efficiency.

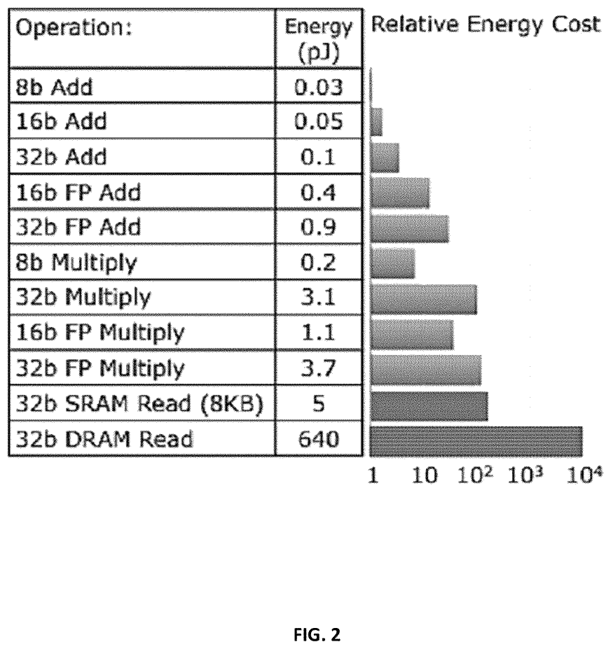

The energy consumption for various arithmetic operations and memory accesses in FIG. 2 shows the relative cost dominated by energy consumption of data movement (red) that is higher than arithmetic operations (blue).

Large last-level caches are included on the CPU chip to scale memory stall time with performance by lowering the miss rate of the processor's caches. Since most of the memory bitcells are idle most of the time, the energy dissipation of large on-chip CPU cache memory is dominated by its leakage. The importance of memory leakage is evident from the fraction of processor power consumed by leakage in large caches with caches and register files (RF) consuming over 50% of the CPU's energy.

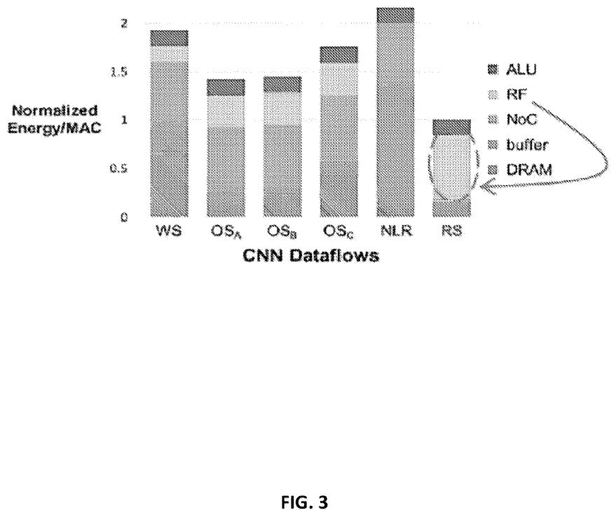

GPUs are widely preferred over CPUs to accelerate AI workloads because Deep Neural Network. (DNN) model training is composed of simple matrix math and convolution calculations, the speed of which can be greatly enhanced if the computations can be carried out in parallel. GPUs use tens of thousands of threads to pursue high throughput performance with extreme multithreading. Extreme multithreading requires a complex thread scheduler as well as a large register file, which is expensive to access both in terms of energy and latency. In GPUs, the bottleneck for DNN processing is in the memory read access—with each multiply-and-accumulate (MAC) operation requiring three-memory read accesses and one memory write access. Row Stationary Dataflows (FIG. 3) that maximize data reuse and local accumulation of data are more energy efficient. FIG. 3 shows the energy consumption by the RF contributing to nearly 70% of the energy of a MAC operation for the more energy efficient row stationary dataflow.

Each thread in a GPU must store its register context on-chip. Unlike CPUs that hide latency of a single thread by using a large last-level on-chip cache, GPUs use a large number of threads and switch between them to hide memory access latency. Just holding the register context. of these threads requires substantial on-chip storage. With so many threads, register files are one of the largest on-chip memory resource in current GPUs. Recently announced commercial GPUs report aggregate on-chip RF array sizes up—to 256 Mb—much larger than last-level, on-chip caches in CPUs

Note that while this paper details the circuit schemes proposed for a 2 port 1R1 W 8T register file bitcell array, these are easily extended to Register File arrays with additional Read Ports by adding an NFET transistor pair (corresponding to the decoupled Read stack in the ‘Read port’ box in FIG. 9) for each additional Read port i with the gate input of the lower NFET-NR1i driven by the cell storage node and the gate input of the upper NFET in the stack, NR2i driven by RWLi. The source terminal of NR1i is connected to a harvesting node V2Li for each Read port i.

Similarly, each additional Write port j is added to the schematic in FIG. 9 of the 1R1 W bitcell by adding NFET PG devices N3j and N4j that connect the cell storage nodes to an added pair of local Write bitlines—BLj, BLBj with the added pair of NFET PG devices N3j, N4j driven by WWLj at their gate inputs. The peripheral circuits associated with the local and global BL for each read/write port i/j are identical to those described in FIG. 8.

### 2. Conventional Two-Port 1R1 W Register File Array Circuits

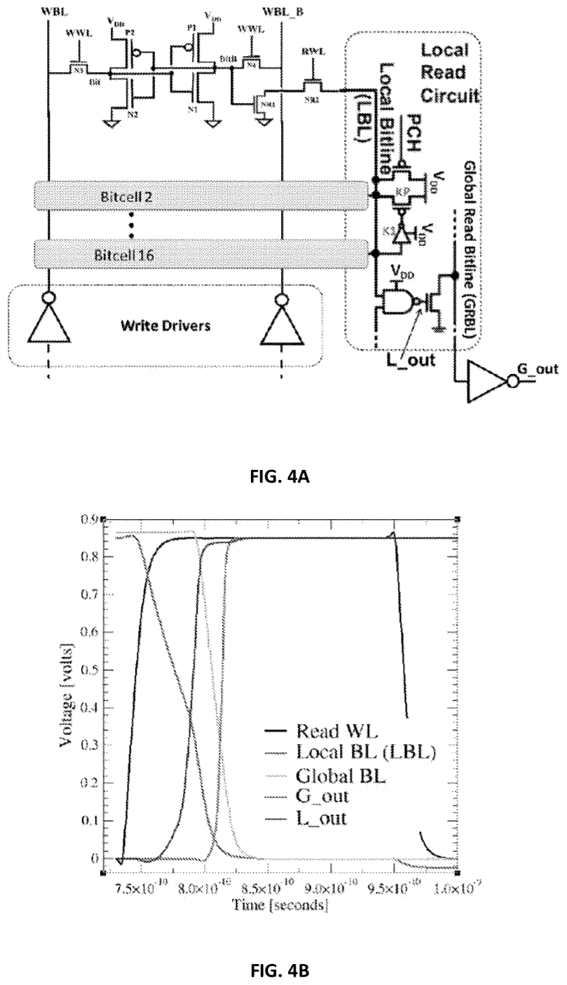

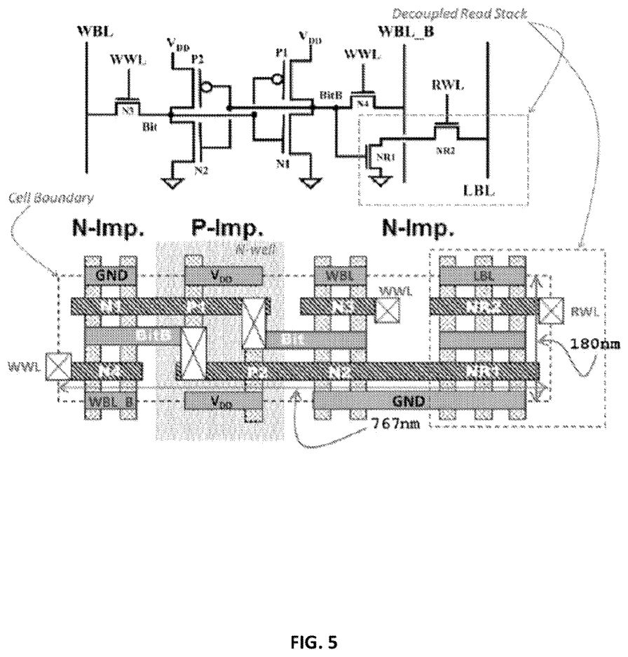

2-Port Register File bitcells FIGS. 4, 5) provide faster signal development rates on the BL and demonstrate lower VMIN when compared to conventional 6T SRAM bitcells. Primarily used when both Read and Write access to memory are desired in the same cycle for high performance processors, 2P RF cells use fast NFET transistors in the read stack to accomplish higher read current at the decoupled read port of the bitcell. The decoupling of the read stack allows a higher read performance without being required to trade it off for higher read stability margins as is required in the 6T SRAM cell. The decoupled read stack also allows the Write margin at low voltages to be independently optimized for lower VMIN. The fast NFET stack (NR1 NR2) in FIG. 4a, 5 driving the decoupled read port in the 2P RF bitcell typically optimized for performance, is also typically leakier than other bitcell devices.

The conventional RT-bitpath assumed serves as a baseline reference relative to which improvements are typically reported by industry and academia alike. All of these recent (within last 4 years) references assume this ‘Domino Read’ full-swing technique as the baseline reference to compare their Register File array implementations with.

2.1 Full-Swing, Short-BL sensing with Logic Gates: Small signal differential sensing—typically used in 6T arrays due to small area overheads and robust operation, is not as attractive for RF arrays because differential sense amps do not track delay scaling in logic circuits and because the small signal development rate on the bitline depends on bitline loading capacitance-dominated by local interconnects in each bitcell which don't scale with device geometries. The scaling of transistor dimensions also degrades random mismatch at the sense amplifier input that translates into larger sense amplifier voltage offsets the BL signal must overcome as a performance overhead.

Alternative large signal sensing schemes for RF arrays, shown in FIG. 4 use a NAND gate and short bit lines (16/32 bits/BL). In this scheme, static CMOS circuits for sensing, short bitlines and rail-rail swings on bitlines eliminate the performance scaling issues seen with differential sensing while the global bitline at an upper metal level routes sensed data across the height of the array at low resistance. This scheme is widely adopted across industry for RF arrays enabling them to deliver much higher performance in GPUs and scale it with logic gate technology at a high cost in (GPU) chip size and in switching and leakage power.

2.2 Dynamic Read-Access: Dynamic circuits that precharge output nodes so they evaluate much faster on arrival of the clock edge with inputs stable during evaluation—are found in practically all fast-memory arrays. Precharge of local and global bitlines and their evaluation by bitcells at the arrival edge of the Read WL select transition are an example in 2P RF bitcell arrays. However, these techniques are energy inefficient since all of the charge discarded (from the LBL and the GRBL in FIG. 4) to the reference ground potential during evaluate must be resupplied during the BL precharge phase before the next Read cycle. In a typical RF Array Instance, as many as 256 local BL columns are accessed by a Read WL in an 8 KB instance. However, only a few rows in the word direction are selected during the same cycle (Read WL, Write WL, Precharge and a few other control signals in the Word direction) making the bit path in an RF array from bitcell to output latch, the dominant (>95%) energy consumption component in an RF array. 2.3 Disturb Current Read Failure avoidance with BL Keeper: The read stack also increases the risk of read failure from disturb current if data at cell node ‘Bit’ in FIG. 4 is a ‘0’ during a concurrent read and write access long the same WL. Because the Write WL half selects the bitcell (write BL pair [BL, BLx] are both precharged to V_{DD}), the cell node ‘Bit’ at ‘0’ typically rises 100-150 mV due to the voltage divider across N2and N3, partially turning on NFET NR1 in the read stack. At relevant Fast N, high T corners (where additional noise by way of VT reductions due to temperature, process and random variations) the local BL (LBL) begins evaluating (with a lower read current) as the gate input of NR1 rises to an effective noise voltage assumed as 300 mV in circuit simulations below. This noise level is sufficient for the bitpath to read out the wrong data at slower cycle times, given a sufficiently wide distribution of Read current in the RF bitcell. The industry-wide adopted solution for this read failure mechanism is to add keeper device KP driven by feedback inverter K1 from the local BL shown in FIG. 4. The impact on signal development time on the LBL at the low T, slow NP corners where the selected bitcell must fight the keeper KP (already in the saturation region) harder to develop signal can be as high as a 20+% signal development time degradation.

2.4 An Industry Solution to Disturb Current read failure: One alternative solution to the keeper described above for disturb current read failure has been to use PFETs instead of NFETs for access devices in the RF bitcell driven-by the Write WL using precharged-low Local Write BLs in half-selected bitcells during simultaneous read and write access of the RF bitcell. This eliminates the voltage bump at the gate of the lower NFET NR1 in the Read stack when ‘Bit’ is 0, but Ion of NR1 is degraded by up to 35% due to a drop in the high node storage level at ‘Bit’ when both RWL and WWL in the same row are simultaneously turned on—effectively degrading read current. The RWL voltage by 15-20% to recover performance when using Write PFET access transistors to eliminate Disturb Current driven Read failure. The power & area overheads in doing so appear significant given the size of bootstrap capacitors required to deliver sufficient charge to the WL. Also, this solution assumes approximately equal drive strengths of NFETs and PFETs due to the introduction of embedded Si/Ge source/drain that enhances hole mobility. Absent this feature in older CMOS platforms, other complications of lowering write margins substantially (and raising write VMIN) could arise when using weaker PFET gates instead of NFETs as access devices driven by the write WL.

2.5 High Leakage through Fast Read Stack: Another negative consequence of the use of the Keeper PFET solution is that when the Bitline is held at V_{DD} by the keeperduring active or standby mode, all bitcells attached to a Local Bitline, are draining high leakage current from the bitline (due to a drop of almost V_{DD} across the top NFET of the read stack) through an already leaky stack—some of which are worse (whose bitcells have ‘Bit’=1 turning on the lower of the two devices in the Read stack). This leakage path is ‘live’ for practically every LBL across the aggregate RF array in a GPU that is powered on. The presence of a keeper circuit also holds the LBL at V_{DD} following a read access where the Bit read in the column was a ‘0’.

2.6 Reliability of NR1 in read stack: NMOS Transistor aging mostly arises from positive bias temperature instability (PBTI), hot carrier injection (HCl), time-dependent dielectric breakdown (TDDB) and electro-migration (EM). In an NFET stack as shown in FIG. 6 below from, with a ‘1’ at terminal ‘B’ (equivalent to the storage node that drives the gate input of transistor NR1 in the decoupled Read stack of the 1R1 W bitcell), the transistor N2 (equivalent to transistor NR1 in the 1R1 W bitcell) will see the most PBTI stress with V_{DD} asserted across its gate oxide at its Source and Drain terminals over extended periods. VT shift of the PD-SRAM bitcell transistors due to PBTI are reported in for stress times up to 100 M secs (3 years) of 10-15 mV which can add to aging from HCl to degrade read stack current/performance and variability even further. With a full V_{DD} across the gate insulator of NR1 (and along the channel of NR2 due to the Keeper) for extended times, for bitcells storing ‘Bit’=1, the above voltage accelerated aging mechanisms due to high-sustained vertical & lateral fields in NR1 & NR2 can lead to PBTI degradation of RF read current and its variability.

New CMOS harvesting circuits are proposed that improve component performance and substantially lower the energy cost of moving data across 2-port/multiport Register File (2P/MP RF) arrays typically implemented in GPU based AI Hardware accelerators. These circuits lower switching energy in local and global bitpaths by over 70% for Read and by over 30% for Write when engaging harvested data to self-limit energy dissipation during a memory access. They also lower bitcell leakage currents along the Read transistor stack pair by over an order of magnitude as a result of-self-disabling of current flow by the rising electric potential barrier of harvested charge.

Proposed sensing circuits double signal development circuit speed along local and global bitlines by comparing a decreasing BL voltage to the increasing electric potential of harvested charge as the evaluation energy expended on the local or global bit path is harvested. These improvements in sensing speed reduce by up to 50+% the WL Select to Output Data delay in a conventional RF array. The proposed bit path circuits also engage harvested charge to provide immunity to disturb current noise during concurrent Read and Write access along a WL-eliminating the performance, area and energy overheads of BL keeper circuits used in conventional 2 port RF Memory arrays.

Proposed circuits improve the reliability of Read performance-limiting bitcell devices by lowering of voltages across their terminals using harvested charge during most of active and standby periods. Area overheads of proposed circuits are expected to be marginal based on device widths of replacements to conventional peripheral circuits and can be further minimized by sharing of devices and their connections between bit slices of the array. Moreover, proposed circuits do not require any changes to the CMOS platform, to the bitcell or to the array architecture with much of the flow for design, verification and test of 2P RF Memory arrays expected to remain unchanged—minimizing risk and allowing integration of proposed circuits into existing products with minimal disruption to schedule and cost. Circuit Simulations are run on a 16 nm FinFET CMOS technology using ASU parameter decks developed and available on a public domain. Additional data on wiring parasitics were obtained from IEDM/ISSCC publications by the foundry of wiring parasitics and bitcell geometries. The Array architecture assumed in simulations is mostly identical to that reported by the Foundry except for a few opportunities to improve circuit and wiring delays.

### 3. Example Array for Circuit Analysis and Comparison

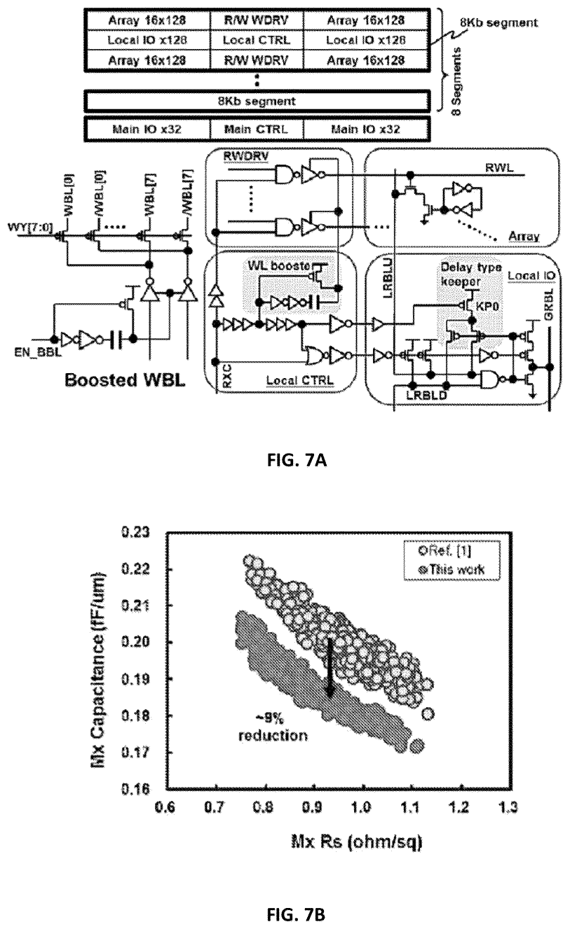

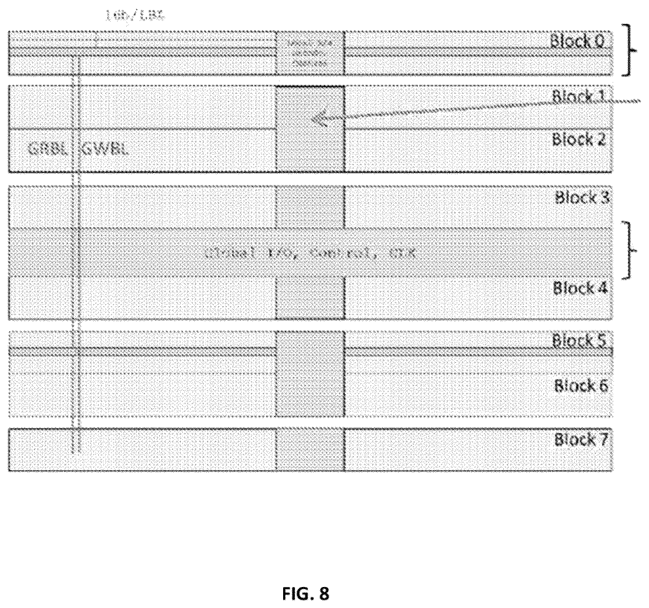

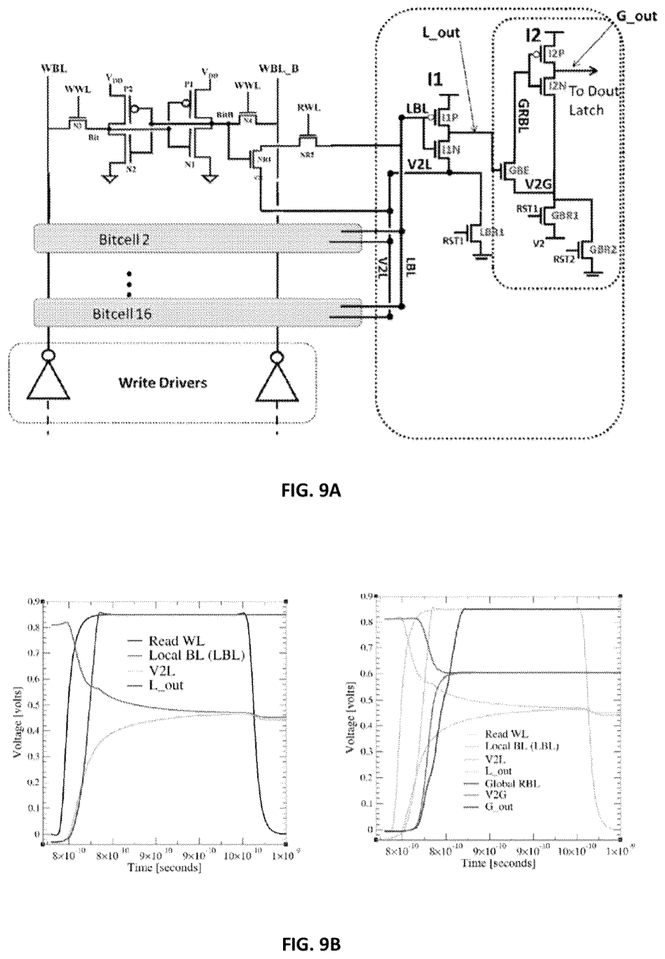

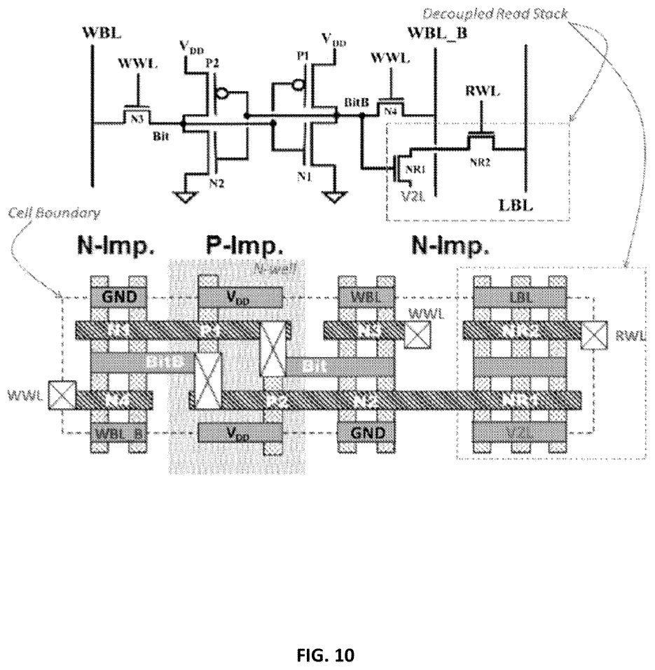

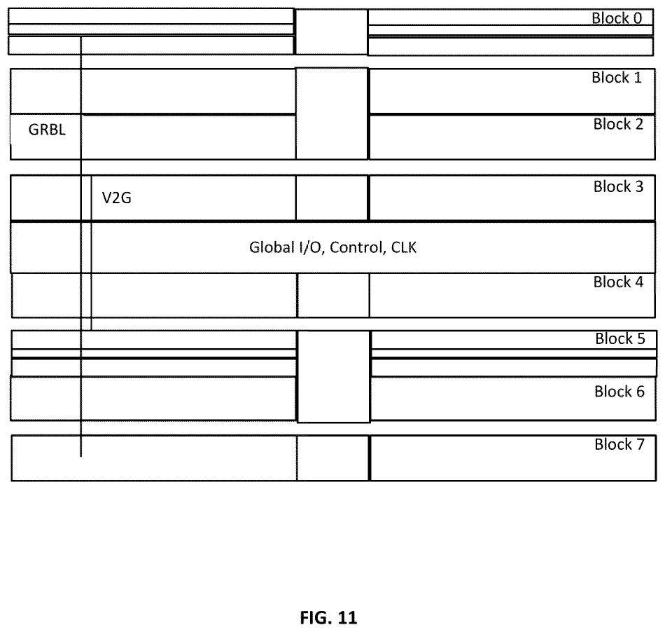

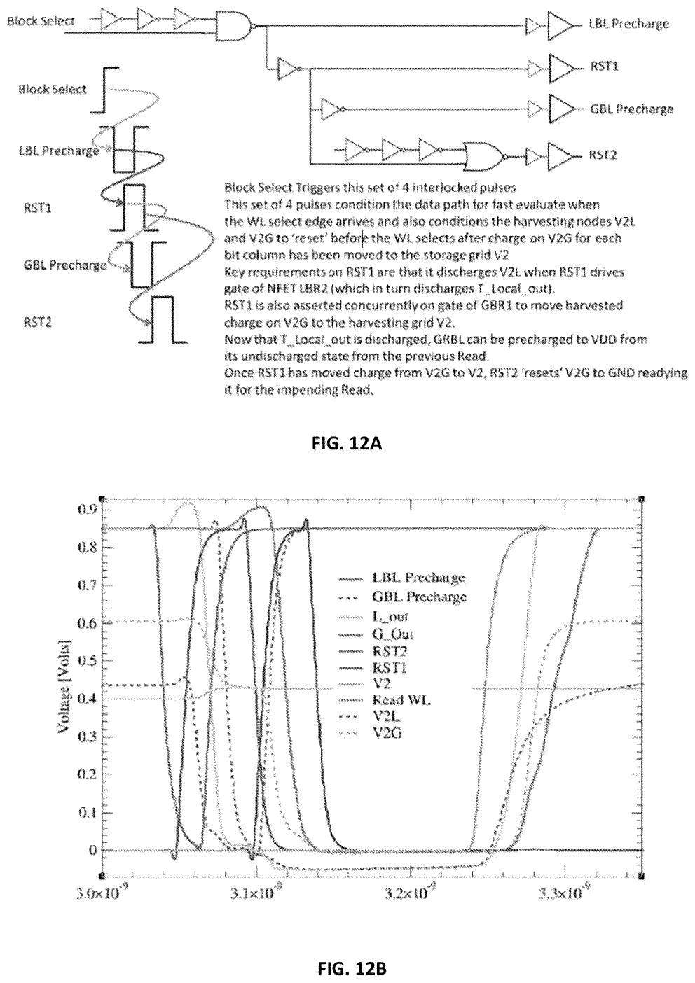

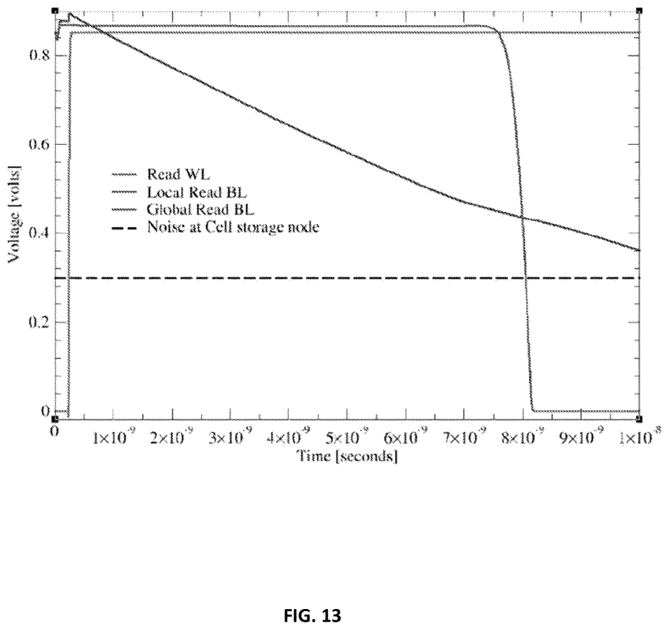

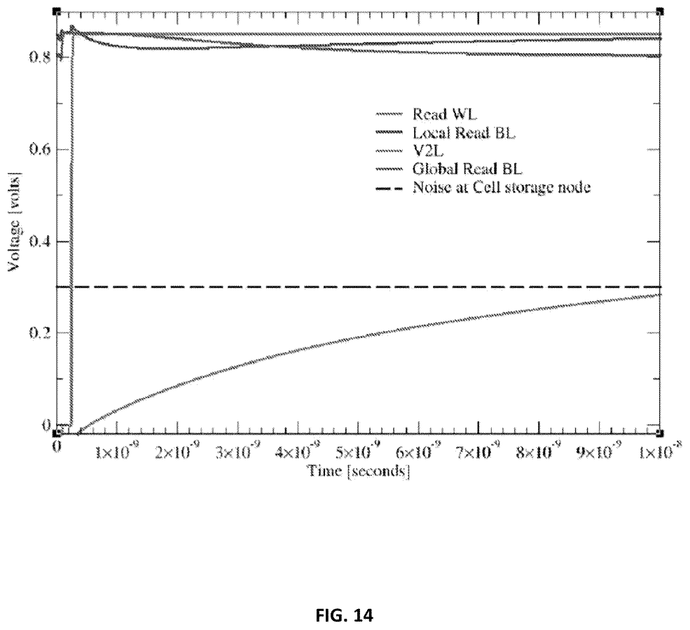

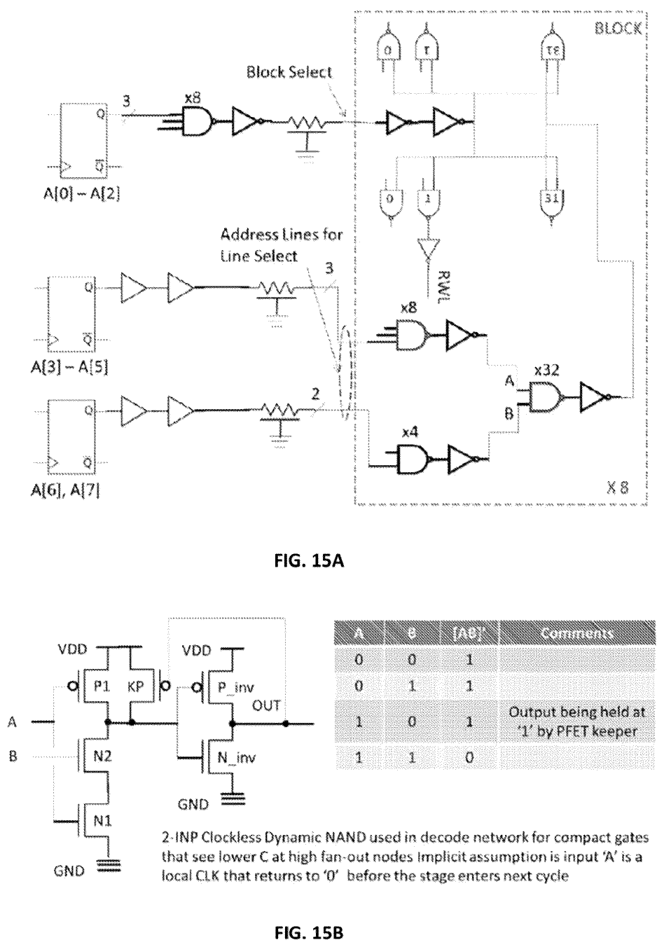

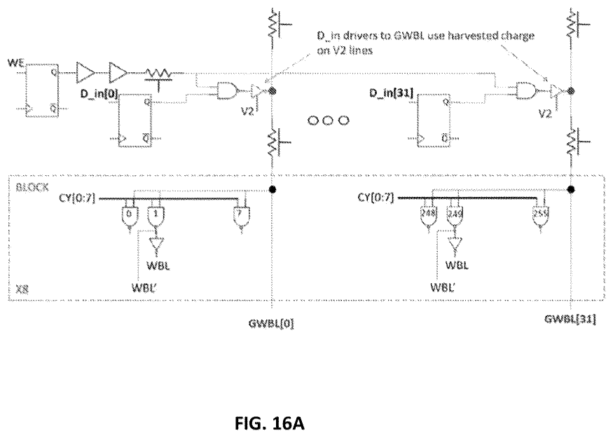

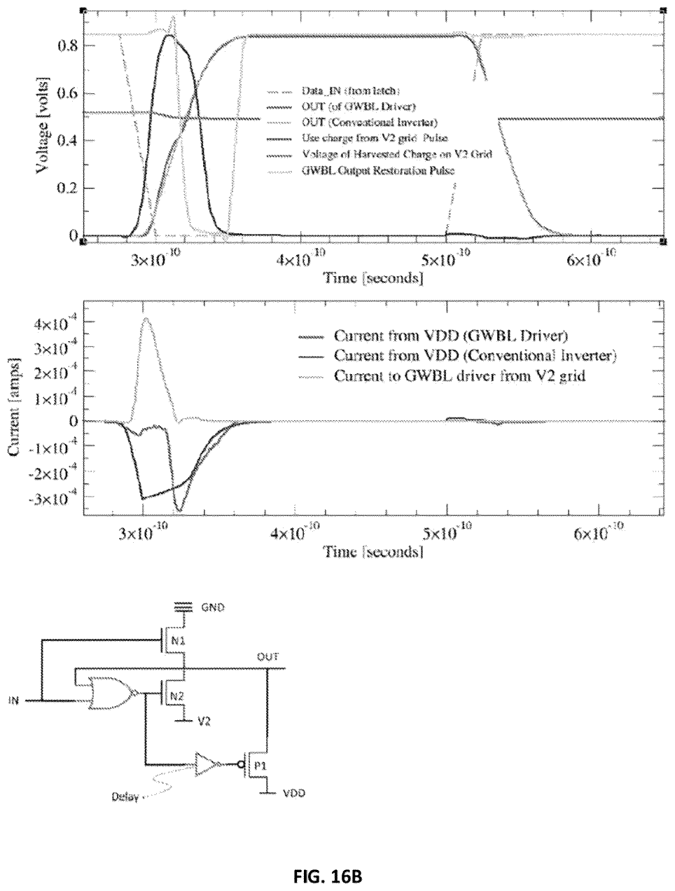

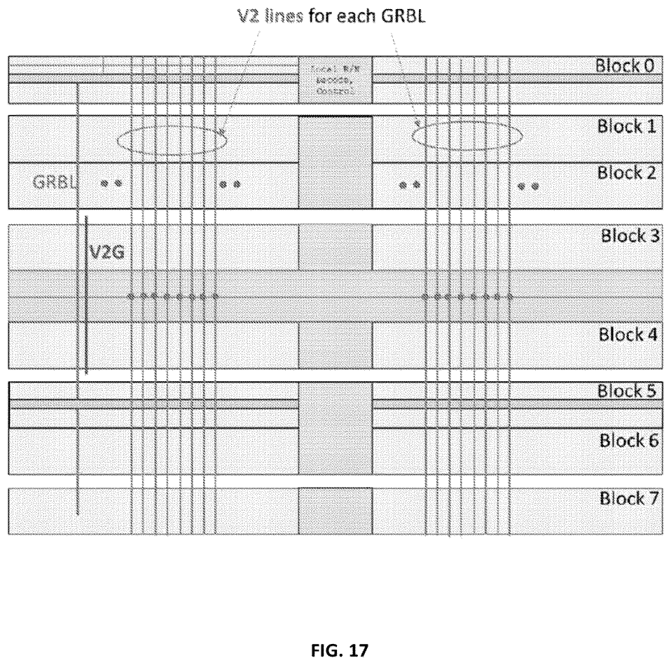

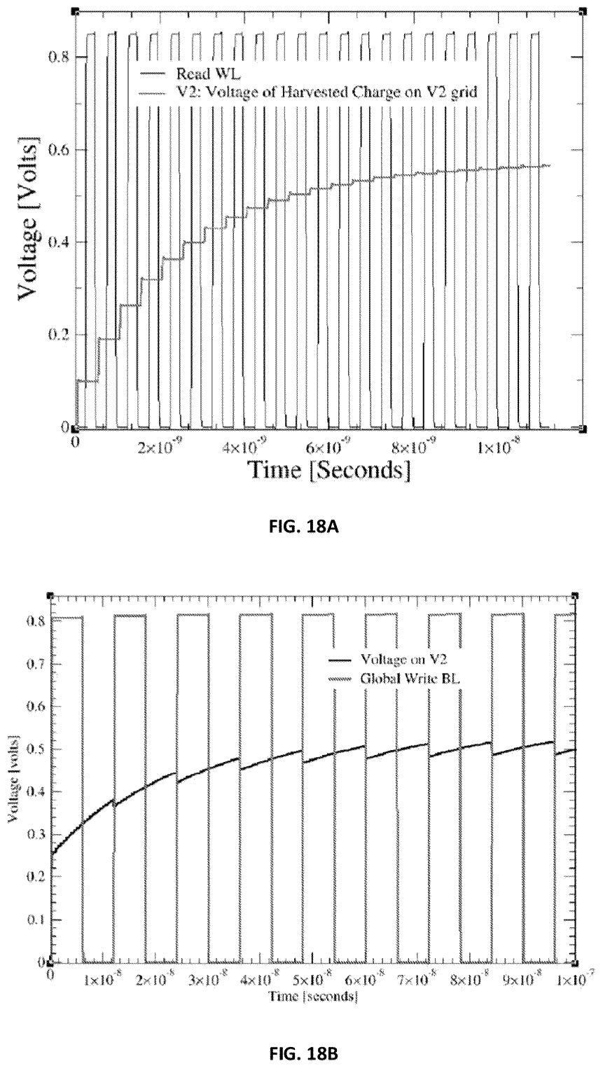

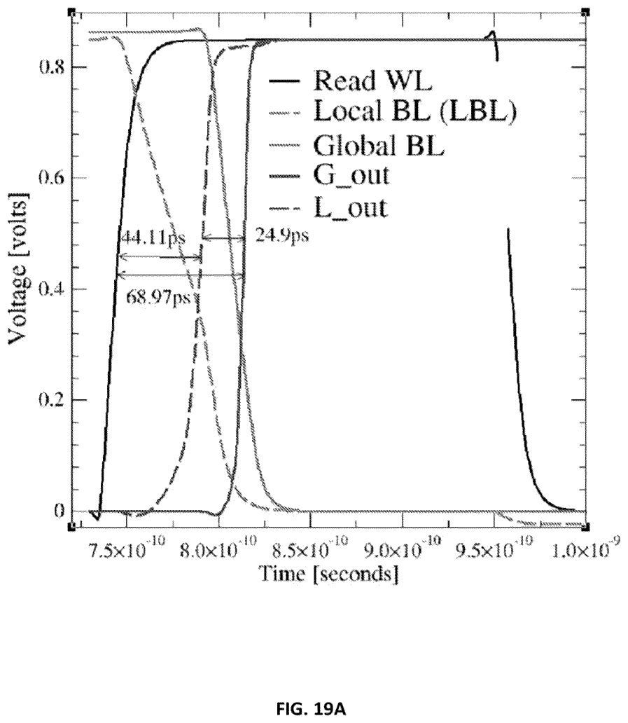

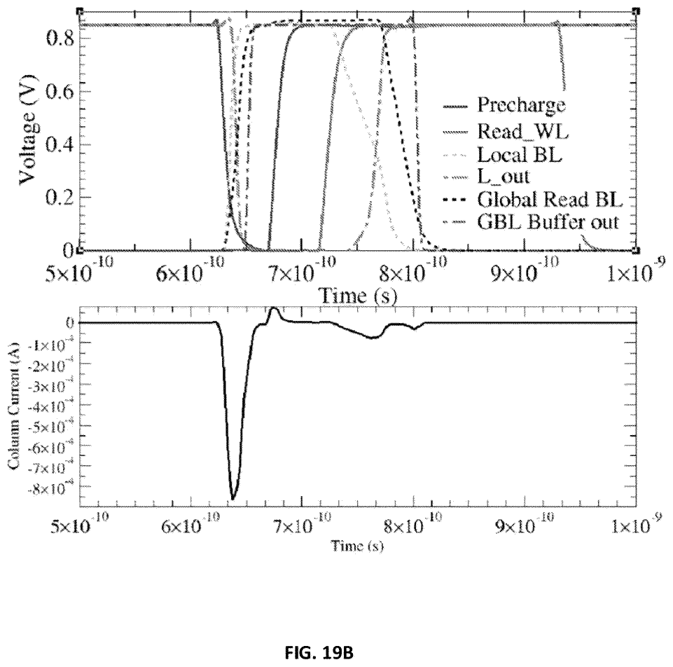

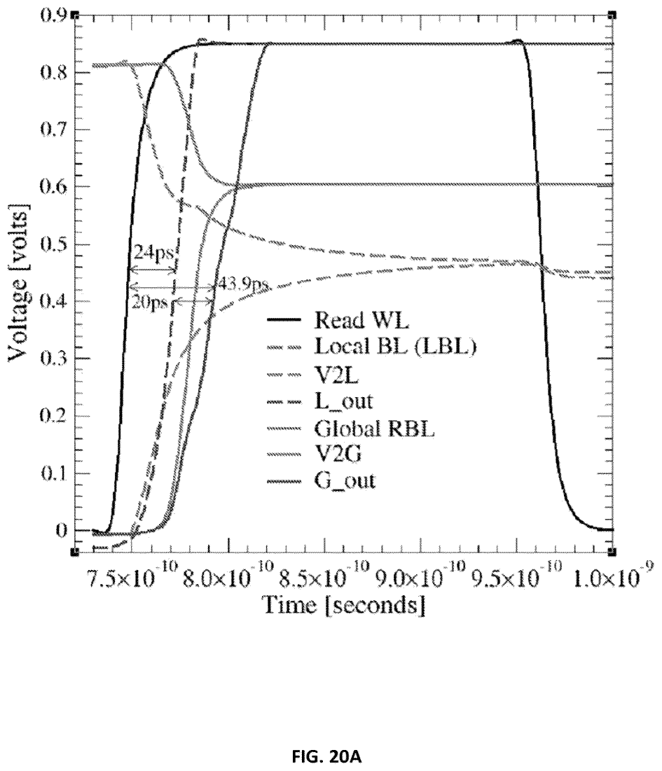

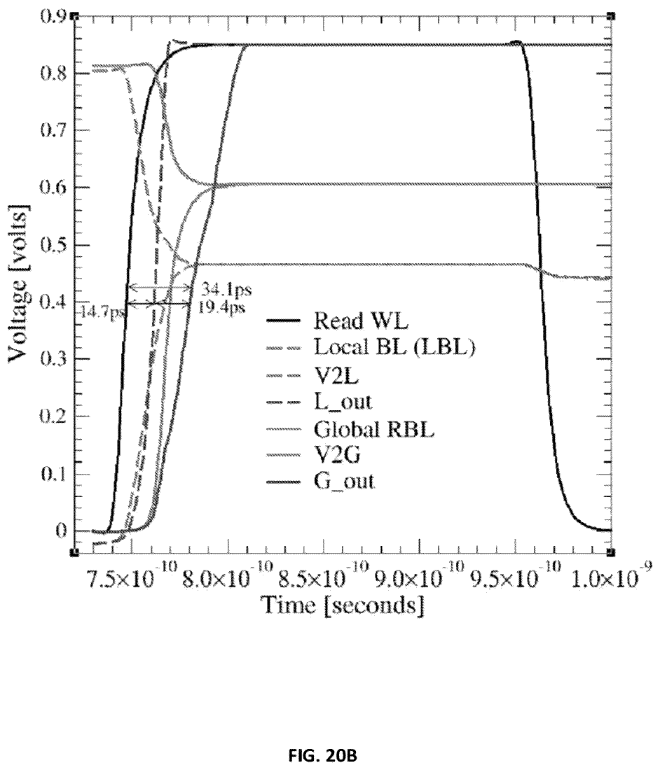

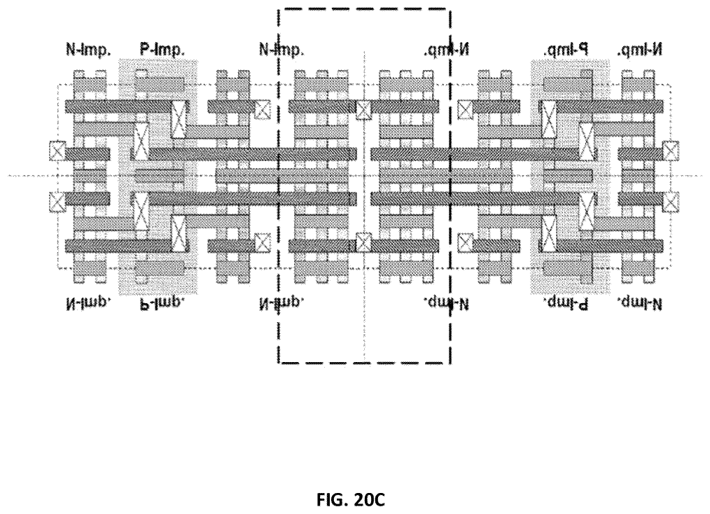

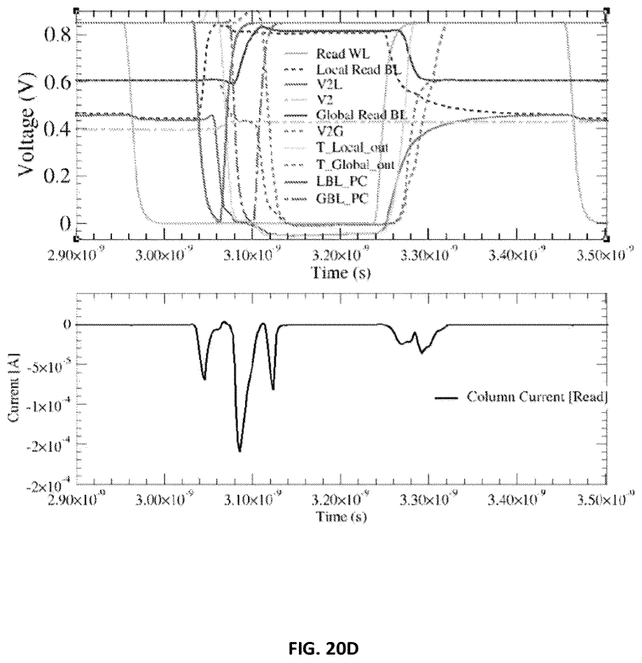

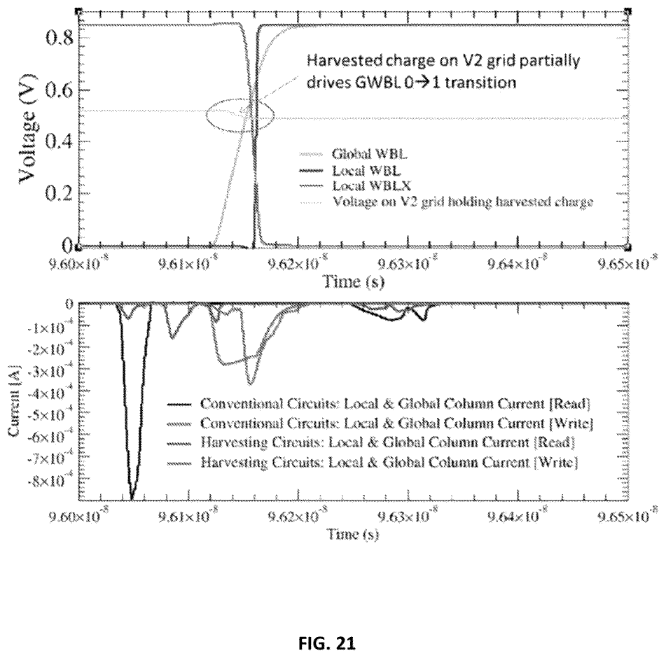

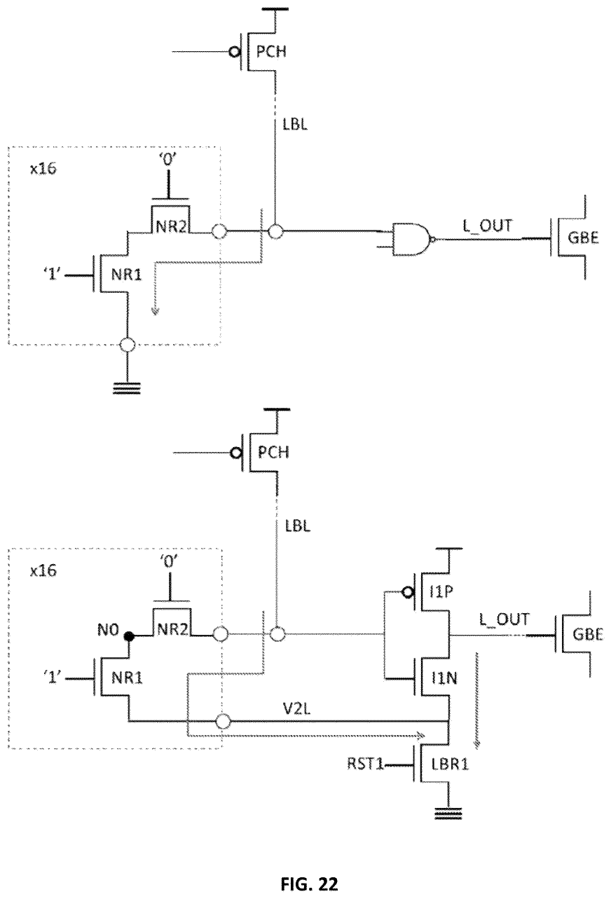

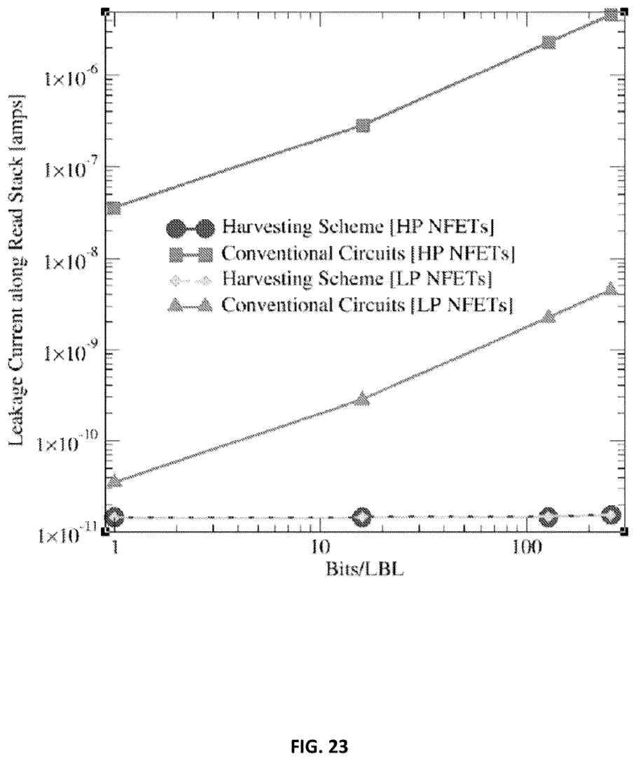

To be able to make quantitative-comparisons between proposed circuits and those used by baseline industry standard designs, a simple, common 8 KB RF Array architecture (FIG. 7a) in 16 nm FF CMOS is assumed. 16 nm high performance and low power device parameter decks from ASU are used in HSPICE circuit stimulations with technology parameters for 16 nm CMOS writing parasitics from IEDM (FIG. 7b) publications by the Foundry. Cell Dimensions (FIG. 5) and wiring parasitics of this RF array are used in the design of peripheral circuits to compare metrics of performance and energy efficiency using either proposed or conventional circuits

The 8 KB array, shown in FIG. 7a has eight 1 Kbyte ‘blocks’ or ‘segments’, each with pairs of 16b×128b subarrays using short 16b BLs. Local peripheral bitpath circuits are placed between the subarrays in a pair on either side of the block. Local Write & Read decoders and control circuits are placed in between the pairs of subarrays. Global I/O and control for the 8 KB instance are placed at the bottom of this column of 8 Blocks as shown in FIG. 7a. The only change to this array (shown in FIG. 8) in the analysis below is the placement of Global I/O, Control and CLK circuits in the middle instead of the bottom, to limit R of pitch constrained Global R/W BLs. Relevant wire R, C and dimensions are shown in FIG. 8. Lateral and vertical dimensions of the array assume a 20% array efficiency where a 20% overhead in X and Y directions are assumed for peripheral circuits.

The ASU decks along with the wiring parasitic data from TSMC reported at IEDM are used in the same array architecture with the same bitcell assumed in both—the baseline reference Register File array as well as the proposed charge harvesting circuit schemes. This apple-apple comparison is what this paper mostly relies on to make quantitative comparisons of performance and power metrics from circuit simulations.

### 4. Operation of Proposed 2P RF Array Bitpath

4.1 Harvest of LBL & GRBL Evaluation Energy: In the proposed scheme, the Source terminal of the NFET read stack in the RF bitcell, NR1 shown in FIGS. 9, 10 is connected to pin ‘V2L’ a metal line shared by all V2L terminals of bitcells that share the same local BL. V2L has a comparable capacitance and resistance to the local BL.

The Read access proceeds as with a conventional RF bitcell, except that charge flowing into the selected bitcells (with ‘Bit’=1) from the precharged Local BL in any given column—is harvested on V2L. This harvesting action raises the voltage on V2L at the same time that LBL loses charge, practically doubling the signal development rate asserted at the gate-source input of the sense-amp (inverter I1 with NFET footer LBR1), until the Read stack self-disables. (Note that the implementation could use a NAND gate instead of inverter I1 with the other input of the NAND driven by a Column select signal if the column is selected by the column multiplexor. The self-disabling action occurs when the read stack devices of the selected bitcells have insufficient gate overdrive to stay in the linear region and move into the subthreshold region as LBL and V2L coverage in voltage (Shown by Red and Green waveforms in FIG. 8 for local or global bit paths). In this scheme, logic circuits used, deliver the benefit of scaling sensing speed with the CMOS platform without the burden of having to consume the energy of full swing operation—as conventional RF arrays are required to.

In FIG. 9a, the GND terminal for a column of 16 bitcells, for the decoupled read stack only, has been replaced with the local harvesting net V2L. The total capacitance of this net is comparable to the total capacitance of the local BL 16 bits long because the wire length in both cases is the same and because the diffusion capacitance contributions by the S/D terminals of NR1 and NR2 to V2L and to LBL respectively is the same.

So, when charge moves from LBL to V2L on selection of any of the bitcells along this column by a Read WL (RWL), at any time, the change in voltage (reduction of LBL and increase in V2L voltage) is about the same. This is verified in FIG. 9b (at bottom) that to first order the LBL converges to the same voltage as V2L when the WL is selected.

The capacitance of V2L is fixed and cannot be changed to charge V2L to a different voltage. So, the sensing inverter for the local BL, I1 triggers when LBL and V2L are within a VT of each other causing its output L_out to make a 0→1 transition as seen in FIG. 9b as well.

For the Global Read BL, the GND terminal of the GRBL evaluation NFET: GBE in FIG. 9a is replaced with the harvesting node V2G. Since the GRBL wire capacitance is large (GRBL spans across all blocks), it is advantageous to raise V2G to a higher voltage as it harvests charge from GRBL, so that a smaller voltage swing on GRBL would be sufficient to resolve the date. This is accomplished by sizing the length of the net V2G to 40% of GRBL (as shown in FIG. 11) so that a small drop in the GRBL voltage as GBE evaluates it, swings V2G up by 2.5× the value of this small swing. As can be seen in FIG. 20, the GRBL drops by only 250 mV because of the capacitance divider sharing harvested charge between GRBL and V2G:

From charge conversion, initial charge=final charge

So,

$${C}_{GBRL} * {V}_{DD} = ( {C}_{GBRL} + {C}_{V 2 G} ) = final charge$$

$$Since {C}_{V 2 G} = 0.4 {C}_{GBRL} ( Fig . 10 )$$

we get.

$$V 2 {G}_{final} = [ {C}_{GBRL} / ( {C}_{GBRL} + {C}_{V 2 G} ) ] * {V}_{DD} = [ 1 / 1.4 ] * 0.85 V = 0.61 V$$

FIG. 20 shows the GRBL (and V2G) settling to this voltage of 0.61V after self-disabling GRBL evaluation, saving a substantial amount of energy per column while also driving the output node of the global sensing inverter 12 in FIG. 9, G_out in less time.

4.2 Fast, energy and area efficient Sense amp action: As the LBL voltage drops, the gate input voltage of I1 approaches I1's logic threshold, which itself moves to a higher voltage of V2L rises with more harvested charge. As the LBL voltage meets the rising logic threshold voltage of I1, the output of I1 L_out rises fast due to the high gain of a CMOS inverter. Since L_out directly drives the gate input of NFET GBB, GBE turns on and the precharged Global Read BL (GRBL) begins discharging as soon as L_out makes its 0→1 transition past the device threshold voltage of NFET GBE.

The precharged Global GRBL discharges to V2G instead of discharging to GND as in the conventional Global RF bitpath. As with the LBL, the converging voltages on GRBL and V2G trigger a low→high transition at the output of inverter 12. A dropping GRBL voltage meets the rising logic threshold voltage of 12. The converging waveforms of GRBL and V2G (red and green waveforms at bottom of FIG. 9b) self-disable the NFET GBE.

Note that since the V2L net has about the same capacitance and dimensions as the LBL. The and V2L voltages thus converge to about the same value ˜VDD/2, by this balanced capacitive divider when they share charge. If V2L were to have a smaller capacitance, V2L could rise to a higher voltage and self-limit the LBL to discharging less than half of its charge. Given the impracticality of using a shorter V2L line (must connect to the GND terminal of the Read stack in each of the RF bit cells along a LBL) and given the smaller capacitance of the LBL (compared to the much larger and longer GRBL), an imbalanced capacitive divider is pursued in the Global BL to raise the voltage of V2G higher than ½ V_{DD} so that V2G can self-limit GRBL discharge sooner, at a voltage closer to V_{DD} than to GND and can this consume much less charge from the V_{DD} grid during a Read access.

FIG. 11 shows the V2G line at about 40% of the length of GRBL-requiring the L_out nets in each bit column from the furthest Blocks 0, 1, 6 & 7 to be routed over an additional 6.9 Um (about 1.3fF). Thus, the Global bitpath circuits NFET GBE, inverter 12 and reset NFETs GBR1 and GRB2 are placed b/w blocks 2 & 3 and b/w block 4 & 5. This placement allows V2G to rise to over 70% of V_{DD} limiting the charge lost by the GRBL (to V2G) on evaluate to less than 30% of what is lost from an equivalent industry-standard RF Global Read BL. Note that the sense amp action is still much faster than the full-swing approach in conventional arrays because the signal development rate seen by 12 is double of what would be available from discharge of a Global Read BL in a conventional RF array.

4.3 Reset of Dynamic nodes before Read Access: The Block Select signal from pre-decoders (FIG. 12A or FIG. 12B) triggers a set of 4 interlocked pulses to condition the local and global Read bitpath before the RWL select edge arrives. They condition the bitpath for fast evaluate and also condition the harvesting nodes V2L and V2G to ‘reset’ to GND before the selected bit cells begin evaluating. Charge harvested on V2G for each bit column from a previous Read is first moved to the storage grid V2 by GRB1 whose gate is driven by pulse RTS1 is that it discharge V2L when RST1 drives gate input of NFET LBR1. Discharge of V2L has the effect of causing the output of I1 to discharge to GND which is where V2L is driven to by the pulse RST1 at gate input of LBR1. RST1 is asserted concurrently on the gate input of NFET GBR1 to move harvested charge on V2G to the harvesting grid V2.

Now that L_out is discharged and GBE is turned off, GRBL can be precharged to V_{DD} from its partially discharged state from a previous Read access. Once RST1 has moved charge from V2G to V2, RST2 ‘resets’ V2G to GND readying it for the impending Read. Also, since L_out has been discharged during RST1, the NFET GBE is turned off enabling the precharged GRBL to hold its precharge voltage of V_{DD} when V2G is discharged to GND to RST2.

All of the 4 signal outputs shown in FIG. 12A or FIG. 12B are generated off the Block select signal during a Read access in the sequence shown according to when each of the 4 signals are triggered off the Block select path. Systematic variations in Process/Voltage/Temp impact all of these gates in proximity to each other, but design considerations on the pulses from the point of generation to point of use within the block require sufficient width of the pulse. For e.g., the Fast-Slow corner for N and P channel FETs respectively at low T could cause the active high pulse (Resets 1, 2 to disappear. Similarly, Slow-Fast corner for N and P channel FETs respectively at low T impacts the active low pulse (local, global precharge). These and other risks would need to be simulated across all relevant corners to enable robust operation. Random variations in device characteristics are unlikely to be significant since these circuits will not be using small geometry dervices.

4.3 Immunity to Disturb Current Failure: The proposed scheme does not require keeper circuitry found in conventional RF array bit paths to avoid read failure when RWL and WWL concurrently select the same row of bit cells as seen in a conventional bitpath. This is illustrated in the circuit simulations of a conventional bitpath without keeper circuits. Cell noise at node ‘Bit’—modeled with a voltage bump at the gate of NR1, can initiate an unintended discharge of the LBL—as seen in FIG. 13, when RWL selects the noisy bitcell. FIG. 13 shows a Read failure occurring when the WL pulse is long enough (and/or if the operating T or voltage or process corner or random VT fluctuations in the Read stack increase read current). The NAND output evaluates incorrectly to V_{DD}, causing the Global Read BL in the conventional RF array to discharge when the LBL voltage drops below the logic threshold of the NAND. The ‘keeper’ solution used by conventional RF arrays that avoids the above disturb current failure, however, increases the WL select →G_out delays by over 20%.

When using the proposed bitpath circuits, keepers are not required since the rising voltage on V2L due to noise voltage at the gate of NFET NR1, self-disables the discharge of the LBL as V2L asymptotically approaches the noise voltage (FIG. 14). The LBL and GRBL can thus be seen in FIG. 14 as maintaining their precharge state of V_{DD} or close enough to V_{DD} without evaluating incorrectly as the conventional RF array would in the scenario described above.

4.4 Compact, fast Decoders: FIG. 15 shows a fast, compact alternative to static CMOS gates. Large fan-outs can be driven by decode stages upstream when smaller loads per fanout are being driven. Since the decode stage outputs (from their inverters) are typically active high, each stage evaluates only when the preceding stages evaluate. This eliminates the need for outputs of preceding stages to drive PFETS as well. The CLK•RE or CLK•WE active high signals drive the full CMOS input ‘A’ in the schematic shown in FIG. 15 restricting switching activity to only the path selected by stable address bits-input B for example as shown in the 2 input AND gate in FIG. 15.

4.5 Write Data Path: For a Multiply Accumulate operation, 3 reads and a Write access are typical. Thus, with an 8:1 Write column multiplexer, a Write access exercises a bit column for about every 24 exercised by a Read access. FIG. 16 shows the data path for a Write access with the Global Write BL (GWBL) driving data to be written across the height of the array with an 8:1 column mux driving this data down the selected local WBL pair.

The GWBL driver schematic in FIG. 16b shows parts highlighted in blue that have devices with much smaller widths (˜⅕ of driver transistors). The NOR gate in this schematic generates an active high pulse whose leading edge is triggered by a 1→0 transition at the input and whose trailing edge is triggered by a 0→1 transition at the output. The leading edge of this active high pulse turns on NFET N2 which begins charging the output with charge harvested on V2. The leading edge of this pulse is inverted and delayed to turn on PFET P1 which charges the output from the VDD grid since the voltage at the output can be charged to no more than the voltage at V2 by NFET N2. The rise in output voltage disables the path from V2 to output with the trailing edge of the active high pulse output of the NOR gate. The PFET P1 completes the output charge to VDD. The presence of a small geometry PFET keeper whose gate input is driven by IN and whose drain terminal is connected to OUT can help avoid any floating nodes. The GWBL driver in a conventional RF array consumes a substantial fraction of the energy expended during a Write access given the large GWBL capacitance and given the large number of GWBL lines being driven (32). The harvest charge during inverter schematic in FIG. 16 lowers the energy consumed by a conventional inverter for the same purpose by over 30% as seen in the waveforms in FIG. 16b. The voltage waveforms from the proposed GWBL driver and an equivalent inverter used in a conventional RF array (with the same GWBL load) are practically identical. Most of the area overhead is from NFET N2 and is not expected to increase the footprint of a conventional inverter by much more than 60-70%.

4.6 Metal Grid that holds Harvest Charge: V2 lines are charged up by Read accesses as shown in (at top of) FIG. 18a asymptotically approaching the maximum voltage (0.62V) set by the voltage V2G is driven to (seen in waveform of V2G in Fgt 9 as 0.62V) by the imbalanced capacitive divider between GRBL and V2G in FIG. 11. Since a Write column is expected to be exercised once every 24 times a Read column is exercised, including Write column accesses at this 1:24 frequency distribution b/w Writes and Reads shows the harvest grid voltage stable around 0.5V (in FIG. 18b). This voltage of V2 is sufficient to lower energy consumed by the GWBL driver by as much as 30%.

4.7 Circuit Speed, Switching Energy Comparisons: FIG. 19a, FIG. 20a and FIG. 20b show circuit speed comparisons between conventional RF array peripheral circuits on the one hand and proposed circuits on the other that use the same bitcell and that use an RF bitcell with LVT NFETS in the Read stack. The WL select→G_out delay components show improvements of 36+% (same bitcell) and 50+% (bitcell with NR1 and NR2 NFETS as LVT devices). FIG. 19b, FIG. 20c and FIG. 21 show the total charge consumed from the power supply by Conventional RF array designs & RF arrays with Proposed circuits with quantitative comparisons organized in Table-I.

The improvements in Read performance of the RF bitcell demonstrated in FIG. 20b without increasing leakage (as seen in FIG. 23) is realized from use of LVT transistors in the decoupled Read stack. While using LVT devices in a bitcell is typically not pursued due to substantial increases in leakage, the 2×2 layout of four adjacent 8T cells in FIG. 20c offers the option to use a LVT mask at no additional cost in area, performance, leakage or additional masks with the LVT mask extending across the column of bitcells

TABLE I
Comparison of Performance & Energy consumption of Proposed
Circuits in 8 KB RF Array with Conventional Circuits

| | | | Read Bitpath | | Write Bitpath | |
|---|---|---|---|---|---|---|
| | WL−> Data_out | | Energy | | Energy | |
| Comparison of RF | | % | | % | | % |
| Array Metrics | Delay | Improvement | Energy | Improvement | Energy | Improvement |
| RF Array with | 68.97 ps | — | 17.26 fJ | — | 13.63 fJ | — |
| Conventional | | | | | | |
| Circuits | | | | | | |
| RF Array with | 43.90 ps | 36.3% | 5.09 fJ | 70.5% | 9.69 fJ | 28.9% |
| Proposed Circuits | | | | | | |
| RF Array with | 34.2 ps | 50.4% | 5.09 fJ | 70.5% | 9.69 fJ | 28.9% |
| Proposed Circuits | | | | | | |
| using LVT NFETs | | | | | | |
| in Read Stack of | | | | | | |
| Cell | | | | | | |

Note:
As shown in FIG. 23, there is no change in the leakage current of the array between the bottom 2 rows of the above Table

4.8 Leakage reduction: FIG. 22 shows the schematics of the leakage paths in the bit cell Read stack in conventional RF arrays and in the RF arrays using proposed circuits. There is no easy outlet for charge to leak away using proposed circuits where V2L, V2G collect evaluation charge and leakage charge as well—that easily leak away in a conventional RF array. The leakage path using proposed circuits is restricted through the LBR1 NFET footer only. The leakage of LBR1 is independent of the device VTs of the NFET read stack (low VT limits set by the ability to resolve data when excess leakage present in a column of bitcells) in the RF bitcell and is also independent of the number of bit cells that share a LBL. The BL and the harvesting node could float up to VDD without consequence to data stored in the 6T part of the RF bitcell. The higher this voltage, the more efficiently charge is harvested by the reset operation directly before a Read access.

1.-14. (canceled)

15. An apparatus, comprising:
a first plurality of multi-port transistor storage cells, each multi-port transistor storage cell from the first plurality of multi-port transistor storage cells including a read port configured to read data and a write port configured to write data, each multi-port transistor storage cell from the first plurality of multi-port transistor storage cells configured to perform at least one of (i) a read data access or (ii) a write data access, each multi-port transistor storage cell from the first plurality of multi-port transistor storage cells comprising a pair of series-connected transistors that electrically couple the read port to a harvest node,
the read port at a second plurality of multi-port transistor storage cells from the first plurality of multi-port transistor storage cells connected to a local bitline terminal, a third plurality of multi-port transistor storage cells from the second plurality of multi-port transistor storage cells connected to the harvest node, a fourth plurality of multi-port transistor storage cells from the first plurality of multi-port transistor storage cells connected to a read word line terminal, the harvest node configured to be reset to a reference ground potential before the read data access, the harvest node configured to be electrically decoupled from the reference ground potential during and after the read data access.

16. The apparatus of claim 15, wherein the third plurality of multi-port transistor storage cells are configured to store charge at a collective capacitance that includes a total capacitance of the harvest node, the harvest node configured to store a harvested charge transferred from the local bitline terminal to the harvest node to increase an electric potential of the harvest node during the read data access.

17. The apparatus of claim 15, further comprising:
a capacitor divider electrically connected between the local bitline terminal and the harvest node, the capacitor divider configured to increase a voltage swing on the harvest node to a magnitude no less than a voltage swing on the local bitline terminal to (i) increase an effective voltage signal development rate, (ii) increase an electric potential of harvested charge at the harvest node, and (iii) trigger a self-disable function of a multi-port transistor storage cell from the local bitline terminal.

18. The apparatus of claim 15, wherein:
a capacitance at the local bitline terminal is configured to be proportional to a number of multi-port transistor storage cells of the second plurality of multi-port transistor storage cells, and
a capacitance at the harvest node is configured to be proportional to a number of multi-port transistor storage cells of the third plurality of multi-port transistor storage cells.

19. The apparatus of claim 15, wherein:
the local bitline terminal is configured to be charged to a voltage substantially equal to a power supply voltage associated with the apparatus prior to the read data access.

20. The apparatus of claim 15, further comprising:
a capacitor divider electrically coupled between the local bitline terminal and the harvest node, the capacitor divider configured to increase an electric potential of the harvest node during the read data access.

21. The apparatus of claim 15, further comprising:
a harvest circuit that includes an inverter with a n-channel field-effect transistor (NFET) footer, a gate terminal of the inverter electrically connected to the local bitline terminal and a source terminal of the inverter electrically connected to the harvest node, a drain terminal of the NFET footer electrically connected to the harvest node and a source terminal of the NFET footer electrically connected to the reference ground potential.

22. The apparatus of claim 21, wherein:
the harvest circuit is configured to be activated with an active high pulse before the read data access begins with an active read word line activation at the fourth plurality of multi-port transistor storage cells, the active high pulse driving a gate terminal of the NFET footer coupled to harvest nodes of the third plurality of multi-port storage cells to cause charge at the harvest nodes to discharge to the reference ground potential.

23. The apparatus of claim 15, further comprising:
a harvest circuit that includes an inverter with a first NFET footer parallel to a second NFET footer, a gate terminal of the inverter electrically connected to the local bitline terminal, a source terminal of the inverter electrically connected to the harvest node, a drain terminal of the first NFET footer electrically connected to the harvest node, a source terminal of the first NFET footer electrically connected to a harvest grid, a drain terminal of the second NFET footer electrically connected to the harvest node, a source terminal of the second NFET footer electrically connected to the reference ground potential.

24. The apparatus of claim 23, wherein:
the harvest circuit is configured to be activated with a first active high pulse and a second active high pulse that (1) does not overlap with the first active high pulse and (2) is before a read word line activation at the fourth plurality of multi-port transistor storage cells, the first active high pulse configured to drive a gate terminal of the first NFET footer and move charge from the harvest node to the harvest grid until a voltage of the harvest node and a voltage of the harvest grid are substantially equal, the harvest grid including a network of capacitors formed from metal wiring included in the apparatus, the harvest grid configured to accumulate charge from the harvest node,
the second active high pulse configured to drive a gate input of the second NFET footer and discharge the harvest node to the reference ground potential such that a voltage of the harvest node is substantially equal a voltage of the reference ground potential.

25. The apparatus of claim 24, wherein:
the harvest circuit is configured to respond to the read data access with the read word line activation selecting the fourth plurality of multi-port transistor storage cells such that a charge at the local bitline terminal associated with each multi-port storage cell from the fourth plurality of multi-port transistor storage cells is shared with the harvest node and the third plurality of multi-port transistor storage cells,
a voltage at the harvest node reset to the reference ground potential before the read word line activation selects the fourth plurality of multi-port transistor storage cells.

26. The apparatus of claim 25 wherein:
a decreasing electric potential at the local bitline terminal and an increasing electric potential at the harvest node (1) self-limits and self-disables passage of read current during the read word line activation and (2) reduces uncertainty of a voltage signal developed at the local bitline terminal by the passage of the read current.

27. The apparatus of claim 26, wherein:
the increasing electric potential at the harvest node due to harvest of electric charge from the passage of the read current is not harvested or discharged to ground until the fourth plurality of multi-port transistor storage cells are re-selected for a subsequent read data access.

28. An apparatus, comprising:
a first plurality of multi-port transistor storage cells, each multi-port transistor storage cell from the first plurality of multi-port transistor storage cells configured to perform at least one of (i) a read data access or (ii) a write data access,
a second plurality of multi-port transistor storage cells that is from the first plurality of multi-port transistor storage cells and that is connected to a local bitline terminal,
a third plurality of multi-port transistor storage cells that is from the second plurality of multi-port transistor storage cells and that is connected to a harvest node,
at least one transistor configured to electrically couple the local bitline terminal to the harvest node,
a fourth plurality of multi-port transistor storage cells that is from the first plurality of multi-port transistor storage cells and that is connected to a read word line terminal,
the harvest node configured to be reset to a voltage of a reference ground potential before the read data access,
the harvest node configured to be electrically decoupled from the reference ground potential during and after the read data access.

29. The apparatus of claim 28, wherein the third plurality of multi-port transistor storage cells are configured to store charge at a collective capacitance that includes a total capacitance of the harvest node, the harvest node configured to store a harvested charge transferred from the local bitline terminal to the harvest node to increase an electric potential of the harvest node during the read data access.

30. The apparatus of claim 28, further comprising:
a capacitor divider electrically connected between the local bitline terminal and the harvest node, the capacitor divider configured to increase a voltage swing on the harvest node to a magnitude no less than a voltage swing on the local bitline terminal to (i) increase an effective voltage signal development rate, (ii) increase an electric potential of harvested charge at the harvest node to dynamically raise a logic threshold voltage of an inverter in a harvest circuit, reduce voltage accelerated aging degradation in transistors of the first plurality of multi-port transistor storage cells, and reduce leakage current from the local bitline terminal to the harvest node and (iii) trigger a self-disable function of a multi-port transistor storage cell from the first plurality of multi-port transistor storage cells from the local bitline terminal to disable passage of read current.

31. The apparatus of claim 28, wherein:
a capacitance at the local bitline terminal is configured to be proportional to a number of multi-port transistor storage cells of the second plurality of multi-port transistor storage cells, and
a capacitance at the harvest node is configured to be proportional to a number of multi-port transistor storage cells of the third plurality of multi-port transistor storage cells.

32. The apparatus of claim 28, wherein:
the local bitline terminal is configured to be charged to a voltage substantially equal to a power supply voltage associated with the apparatus prior to the read data access.

33. The apparatus of claim 28, further comprising:
a capacitor divider between the local bitline terminal and the harvest node, the capacitor divider configured to increase an electric potential of the harvest node during the read data access.

34. An apparatus, comprising:
a first plurality of multi-port transistor storage cells, each multi-port transistor storage cell from the first plurality of multi-port transistor storage cells configured to perform at least one of (i) a read data access or (ii) a write data access,
a second plurality of multi-port transistor storage cells that is from the first plurality of multi-port transistor storage cells and that is connected to a local bitline terminal,
a third plurality of multi-port transistor storage cells that is from the second plurality of multi-port transistor storage cells and that is connected to a harvest node,
at least one transistor configured to electrically couple the local bitline terminal to the harvest node,
the harvest node configured to be reset to a voltage of a reference ground potential before the read data access,
the harvest node configured to be electrically decoupled from the reference ground potential after the read data access.
